(19) United States
(12) Patent Application Publication
(10) Pub. No.: US 2014/0053902 A1
(43) Pub. Date: Feb. 27, 2014

(54) PHOTOELECTRIC CONVERSION ELEMENT AND SOLAR CELL

(71) Applicant: KABUSHIKI KAISHA TOSHIBA, Tokyo (JP)

(72) Inventors: Soichiro Shibasaki, Tokyo (JP); Mutsuki Yamazaki, Kanagawa (JP); Naoyuki Nakagawa, Tokyo (JP); Shinya Sakurada, Tokyo (JP); Michihiko Inaba, Kanagawa (JP)

(73) Assignee: KABUSHIKI KAISHA TOSHIBA, Tokyo (JP)

(21) Appl. No.: 14/069,527

(22) Filed: Nov. 1, 2013

Related U.S. Application Data
(63) Continuation-in-part of application No. PCT/JP2012/061109, filed on Apr. 25, 2012.

(30) Foreign Application Priority Data
May 6, 2011 (JP) 2011-103718

(51) Int. Cl. H01L 31/032

(52) U.S. Cl. CPC H01L 31/0322
USPC 136/262

(57) ABSTRACT

A photoelectric conversion element of an embodiment includes a p-type light absorbing layer containing Cu, at least one or more Group IIIb elements selected from the group including Al, In and Ga, and at least one or more elements selected from the group including O, S, Se and Te; and an n-type semiconductor layer formed on the p-type light absorbing layer and represented by any one of Zn_{1-y}M_{y}O₁₋ₓSₓ, Zn_{1-y-z}Mg_{z}M_{y}O (wherein M represents at least one element selected from the group including B, Al, In and Ga), and GaP with a controlled carrier concentration, while x, y and z in the formulas Zn_{1-y}M_{y}O₁₋ₓSₓ and Zn_{1-y-z}Mg_{z}M_{y}O satisfy the following relations: 0.55≦x≦1.0, 0.001≦y≦0.05, and 0.002≦y+z≦1.0.

### CROSS-REFERENCE TO RELATED APPLICATION

This application is a continuation-in-part (CIP) application based upon and claims the benefit of priority from Japanese Patent Applications No. 2011-103718, filed on May 6, 2011; and International Application PCT/JP2012/061109, the International Filing Date of which is Apr. 25, 2012 the entire contents of which are incorporated herein by reference.

### FIELD

Embodiments described herein relate generally to a photoelectric conversion element and a solar cell.

### BACKGROUND

In regard to solar cells for example, the development of compound-based thin film photoelectric conversion elements that use semiconductor thin films as light absorbing layers has been in progress. Among others, thin film photoelectric conversion elements having, as a light absorbing layer, a p-type semiconductor layer having a chalcopyrite structure, such as Cu(In, Ga)Se₂ which is so-called CIGS, exhibit high conversion efficiency, and the industrial application of those elements is highly expected. The conversion efficiency, η, of the photoelectric conversion element is represented by the equation: η=Voc·Jsc·FF/P·100, using the open circuit voltage Voc, the short circuit current density Jsc, the output factor FF, and the incident power density P. As it is obvious from this, when the open circuit voltage, the short circuit current and the output factor respectively increase, the conversion efficiency increases.

In theory, as the band gap between the p-type light absorbing layer and the n-type semiconductor layer becomes larger, the open circuit voltage increases, but the short circuit current density decreases. When the change in the efficiency is viewed as a function of the band gap, the maximum value lies in the range of approximately 1.4 eV to 1.5 eV. The band gap of Cu(In, Ga)Se₂ increases with the concentration of Ga, and it is known that when the ratio of Ga/(In +Ga) is controlled to a value approximately close to 0.3, a photoelectric conversion element having satisfactory conversion efficiency is obtained.

However, the compound-based thin film photoelectric conversion materials are such that the open circuit voltage is lower than the value that may be estimated from the value of the band gap, and is further lower than that for Cu(In, Ga)Se₂ having a high gallium (Ga) concentration. Thus, it is necessary to solve this problem.

In the case of a compound-based thin film photoelectric conversion element such as Cu(In, Ga)Se₂, since the p-type semiconductor layer and the n-type semiconductor layer are of different materials systems (heterostructures), the positional relation of the conduction band minimum (CBM), which is the lower edge of the conduction band of the p-type semiconductor layer, and the CBM of the n-type semiconductor layer, and the position of the Fermi levels of the p-type semiconductor layer and the n-type semiconductor layer are important to increase the open circuit voltage.

In Cu (In, Ga) Se₂ photoelectric conversion elements, CdS is used as the n-type semiconductor layer. In this case, the values of CBM are approximately the same; however, along with an increase in the Ga concentration, the value of CBM of the p-type semiconductor layer (light absorbing layer) becomes smaller than the value of CBM of the n-type semiconductor layer, so that the maximum value of the open circuit voltage at the time point when the position of the Fermi level is optimized, is lowered. This decrease is significant mainly in the open circuit voltage value when the amount of light irradiation is small. In addition, since there is a risk that cadmium (Cd) in cadmium sulfide (CdS) used in the n-type semiconductor layer may have an adverse effect on human body, there has been a demand for a substitute material.

### BRIEF DESCRIPTION OF THE DRAWINGS

FIG. 1 is a conceptual diagram of a photoelectric conversion element according to embodiments of the present invention.

FIG. 2 is a diagram illustrating the relation between the positions of the lower edges of the conduction bands of the p-type light absorbing layer and the n-type semiconductor layer according to the embodiments, and the open circuit voltage.

FIG. 3 is a diagram illustrating the respective band positions of GaP, MgO, ZnO, ZnS, CdS, CuInTe₂, CuIn₃Te₅, CuInSe₂, CuGaSe₂ according to the embodiments.

### DETAILED DESCRIPTION

A photoelectric conversion element of an embodiment includes: a p-type light absorbing layer containing copper (Cu), at least one or more Group IIIb elements selected from the group including aluminum (Al), indium (In) and gallium (Ga), and at least one or more elements selected from the group including oxygen (O), sulfur (S), selenium (Se) and tellurium (Te); and an n-type semiconductor layer formed on the p-type light absorbing layer and represented by any one of Zn_{1-y}M_{y}O₁₋ₓSₓ, Zn_{1-y-z}Mg_{z}M_{y}O (wherein M represents at least one element selected from the group including boron (B), Al, In and Ga), and gallium phosphide (GaP) with a controlled carrier concentration, in which x, y and z in the formulas Zn_{1-y}M_{y}O₁₋ₓSₓ and Zn_{1-y-z}Mg_{z}M_{y}O satisfy the relations: 0.55≦x≦1.0, 0.001≦y≦0.05, and 0.002≦y+z≦1.0.

Embodiments of the invention will be described below with reference to the drawings.

(Photoelectric Conversion Element)

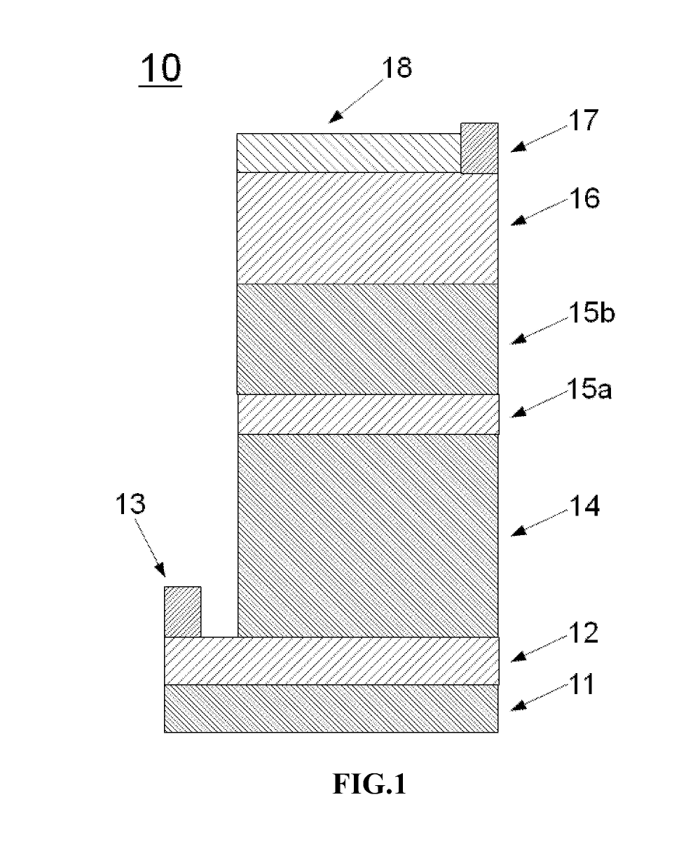

The photoelectric conversion element according to the embodiment of FIG. 1 is a thin film type photoelectric conversion element including a soda lime glass plate 1; a lower electrode 2 formed on the soda lime glass plate 1; a p-type light absorbing layer 3 formed on the lower electrode 2; an n-type semiconductor layer 4 formed on the p-type light absorbing layer 3; a semi-insulating layer 5 formed on the n-type semiconductor layer 4; a transparent electrode 6 formed on the semi-insulating layer 5; an upper electrode 7 and an antireflective film 8 formed on the transparent electrode 6. In this embodiment, a photoelectric conversion element having the configuration illustrated in FIG. 1 is described as an example, but as long as a p-type light absorbing layer 3 is formed between the lower electrode 2 and the upper electrode 7, and an n-type semiconductor layer 4 is formed on the p-type light absorbing layer 3, there are no particular limitations on other parts of the configuration.

The p-type light absorbing layer 3 of the embodiment is preferably a compound semiconductor containing a Group Ib element; at least one or more Group IIIb elements selected from the group including Al, In and Ga; and at least one or more Group VIb elements selected from the group including O, S, Se and Te. Among the Group Ib elements, it is more desirable to use Cu because a p-type semiconductor is more easily formed. Furthermore, among the Group IIIb elements, it is more desirable to use In because when In is used in combination with Ga, it is easier to adjust the size of the band gap to a desired value. Also, among the Group VIb elements, it is more desirable to use Te because a p-type semiconductor can be easily formed. Specifically, compound semiconductors such as Cu (In, Ga) (S, Se)₂, Cu (In, Ga) (Se, Te)₂, Cu (In, Ga)₃(Se, Te)₅, and Cu (Al, Ga, In) Se₂, and Cu₂ZnSnS₄ can be used, and more specifically, compound semiconductors such as CuInSe₂, CuInTe₂, CuGaSe₂, and CuIn₃Te₅ can be used, as the p-type light absorbing layer 3.

These desirable elements are such that if the position of the CBM is high, that is, if the energy is small, compounds containing relatively larger proportions of Te, Ga and S are advantageous.

The n-type semiconductor layer 4 of the embodiment is used as a buffer layer, and an n-type semiconductor having its Fermi level controlled is preferred for the layer, so that a photoelectric conversion element having a high open circuit voltage can be obtained.

Thus, according to the embodiment, any one of Zn_{1-y}M_{y}O₁₋ₓSₓ, Zn_{1-y-z}Mg_{z}M_{y}O (wherein M represents at least one element selected from the group including B, Al, In and Ga), and n-type GaP with a controlled carrier concentration, is preferred as the n-type semiconductor layer 4.

Among the materials for the n-type semiconductor layer 4 described above, Zn_{1-y}M_{y}O₁₋ₓSₓ and Zn_{1-y-z}Mg_{z}M_{y}O (wherein M represents at least one element selected from the group including B, Al, In and Ga) will be described.

As the n-type semiconductor layer 4 of photoelectric conversion elements, ZnO₁₋ₓSₓ and Zn_{1-z}Mg_{z}O are conventionally known as materials for n-type semiconductor layers, for which the conduction band minima (CBM) can be adjusted. However, due to the deficiency of O or S, or to the difference in the stoichiometric ratios, it is difficult to control the Fermi level to an extent comparable to the object of increasing the open circuit voltage, only by introducing carriers. Furthermore, carrier doping achieved by utilizing defects has a problem of decreased crystallinity. Thus, the Fermi level was adjusted by partially substituting Zn of the above formula ZnO₁₋ₓSₓ or Zn_{1-z}Mg_{z}O, with one or more elements (carriers) selected from the group including B, Al, In and Ga, and thus the open circuit voltage was increased.

Here, when the value of x, which represents the amount of S, is 0.5 or less, the position of CBM of the p-type light absorbing layer 3 is relatively high (that is, the energy of CBM is small), and therefore, an increase in the open circuit voltage cannot be expected. For that reason, it is preferable that x satisfies the relation of 0.55≦x≦1.0. For example, when the p-type light absorbing layer 3 is a semiconductor layer having a relatively low CBM such as in the range of equal to or greater than 4.3 eV and equal to or less than 4.6 eV, as in the case of CuInSe₂, there is a tendency that as the value of x increases, the barrier of the n-type semiconductor layer 4 increases, and the short circuit current value rapidly decreases. Therefore, x is preferably equal to or greater than 0.55 and equal to or less than 0.7, and more preferably equal to or greater than 0.6 and equal to or less than 0.68. On the other hand, when the p-type light absorbing layer 3 is a semiconductor layer having a relatively high CBM such as in the range of equal to or greater than 3.5 eV and equal to or less than 4.0 eV, as in the case of CuInTe₂, it is desirable that x be in a range closer to 1, for example, in the range of equal to or greater than 0.65 and equal to or less than 1.0, and more desirably equal to or greater than 0.68 and equal to or less than 0.85. When the p-type light receiving layer is a semiconductor layer having an intermediate value of CBM such as in the range of equal to or greater than 3.8 eV and equal to or less than 4.3 eV, as in the case of CuGaSe₂, it is desirable that x be in an intermediate range of equal to or greater than 0.6 and equal to or less than 0.8, and more desirably equal to or greater than 0.65 and equal to or less than 0.75.

When the value of y is 0, an effective carrier concentration occurs due to defects, and therefore, the open circuit voltage tends to become smaller, particularly in the case where the amount of light irradiation is small. On the other hand, if the value of y is too large, there is a risk that a decrease in the mobility within the n-type semiconductor layer 4 caused by M may occur, the recombination ratio of carriers inside the n-type semiconductor layer 4 may increase, and as a result, the short circuit current density may be decreased. Therefore, the value of y is desirably in the range of 0.001≦y≦0.05. This value of y is preferably in the range of 0.005≦y≦0.04, and more preferably in the range of 0.01≦y≦0.03. Furthermore, this value of y may also be in the range of y>0.05 as long as non-metallic temperature dependency is exhibited, and the value of y may increase or decrease depending on the type of dopant.

Mg is an element adjusting the CBM to an appropriate range, and if the value of z, which is the amount of Mg, is too large, the crystal structure of Zn_{1-y-z}Mg_{z}M_{y}O turns into a NaCl type structure, which is not desirable. Thus, y+z is preferably such that 0.001<y+z 0.55, and also, it is preferable that the value of y+z be 0.2 or greater, because the crystal structure turns into a ZnO (Wurtzite) type structure. On the other hand, if the value of y is too large, there is a risk that a decrease in the mobility within the n-type semiconductor layer 4 caused by M may occur, the recombination ratio of carriers inside the n-type semiconductor layer 4 may increase, and as a result, the short circuit current density may be decreased. Thus, the value of y is desirably in the range of 0.001≦y≦0.05.

The value of z in the formula Zn_{1-y-z}Mg_{z}M_{y}O is desirably such that 0<z≦0.5. Among others, when the p-type light absorbing layer 3 is a semiconductor layer having a relatively low CBM such as in the range of equal to or greater than 4.3 eV and equal to or less than 4.6 eV, as in the case of CuInSe₂, the value of z is preferably in the range of 0.1≦z≦0.4, and more preferably in the range of 0.15≦z≦0.3, for the same reasons. Furthermore, when the p-type light absorbing layer 3 is a semiconductor layer having an intermediate value of CBM such as in the range of equal to or greater than 3.8 eV and equal to or less than 4.3 eV, as in the case of CuGaSe₂, it is desirable that the value of z is preferably in the range of 0.15≦z≦0.5, and more preferably in the range of 0.2≦z≦0.5, for the same reasons. Also, when the p-type light absorbing layer 3 is a semiconductor layer having a relatively high CBM such as in the range of equal to or greater than 3.5 eV and equal to or less than 4.0 eV, as in the case of CuInTe₂, the value of z is preferably in the range of 0.2≦z≦0.5, and more preferably in the range of 0.25≦z≦0.5.

Among the materials for the n-type semiconductor layer 4 described above, the n-type GaP with a controlled carrier concentration will be described. GaP is known as a material for semiconductor substrates, but GaP has not been used for the buffer layer of photoelectric conversion elements. In the GaP type buffer layer used in the n-type semiconductor layer 4 of the embodiment, the open circuit voltage was increased by doping carriers, and thereby regulating the Fermi level. It is desirable that the GaP of the embodiment be doped with one or more elements selected from the group including S, Se and Te. In order to adjust the open circuit voltage, Ga_{α}Al_{1-α}P in which a portion or the entirety of Ga has been substituted with Al, may also be used.

The carrier concentration of the above-mentioned element in GaP is desirably equal to or greater than 10¹⁴ cm⁻³ and equal to or less than 10²¹ cm⁻³. The carrier concentration is preferably equal to or greater than 2.0×10¹⁴ cm⁻³ and equal to or less than 5.0×10¹⁷ cm⁻³, and more preferably equal to or greater than 3.0×10¹⁴ cm⁻³ and equal to or less than 8.0×10¹⁶ cm⁻³.

Next, selection of the materials for the p-type light absorbing layer 3 and the n-type semiconductor layer will be described.

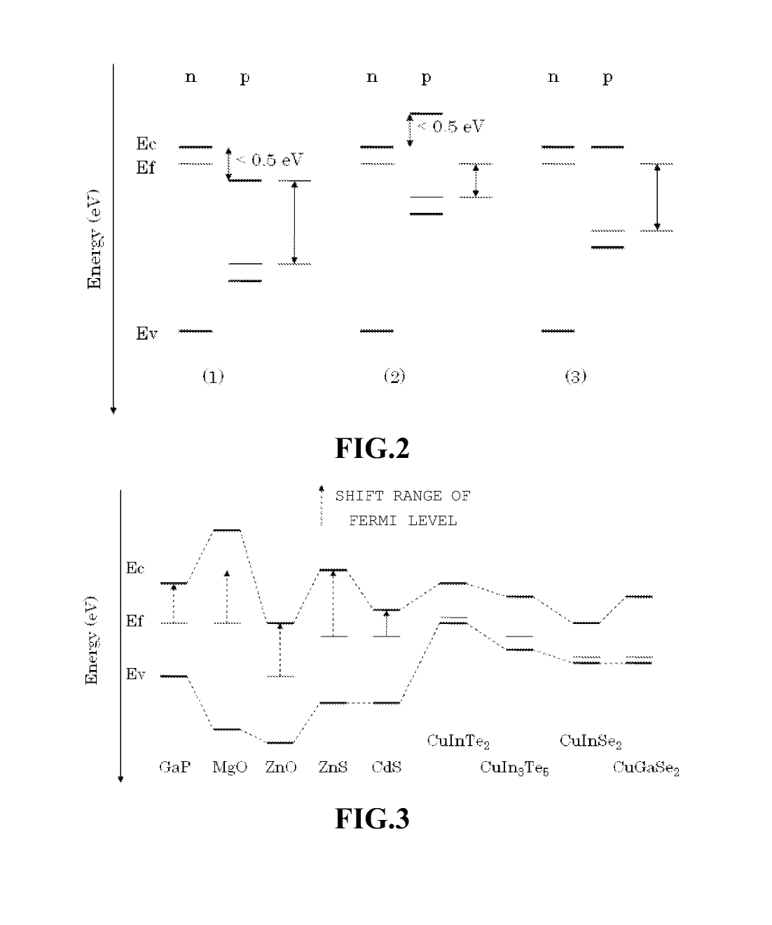

The position of CBM of the p-type light absorbing layer 3, E_{cp} (eV), and the position of CBM of the n-type semiconductor layer, E_{cn} (eV), may vary depending on the material system, and the presence or absence of the exhibition of rectifying properties when a p-n junction is produced can be determined from the magnitudes of the work function and the activation gap. When a p-n junction is produced, in the case of using the p-n junction as a photoelectric conversion element as illustrated in FIG. 2, the size of the band gaps of the p-layer and the n-layer generally exceeds 1 eV. Therefore, if the difference in the position of the lower edge of the conduction band (CBM) between the p-layer and the n-layer, ΔEc (=|E_{cp}−E_{cn}|) is equal to or larger than half of the band gap of the layer with smaller band gap, the effects of the embodiment can be verified (when the band gap is 1.0 eV, ΔEc is desirably 0.5 eV or less). It is desirable that ΔEc be 0.3 eV or less, and ultimately, it is more desirable that ΔEc=0.0 as in the case of homojunction, while in a practical sense, it is more desirable that ΔEc is 0.1 eV or less.

The difference of CBM can be estimated by determining the valence band positions of the p-type light absorbing layer 3 and the n-type semiconductor layer 4 by x-ray photoelectron spectroscopy (XPS) from reference substances (for example, gold (Au)), and adding the sizes of the band gaps of the two layers that may be determined by an optical measurement or the like. In the case where there are no photocarriers, when E_{cp} is higher than E_{cn}, the maximum value of the open circuit voltage is defined as the size between E_{cn} and the Fermi level of the p-type light absorbing layer 3; however, when E_{cp} is lower than E_{cn}, the maximum value of the open circuit voltage is determined as the size between the Fermi levels of the p-type semiconductor layer 3 and the n-type semiconductor layer 4. Furthermore, when the Fermi level of the n-type semiconductor layer 4 exists at a place higher than the position of CBM of the p-type light absorbing layer 3, the electrons of the n-type semiconductor layer 4 and the carriers on the p-type light absorbing layer 3 side cancel each other, and the maximum value of the open circuit voltage decreases to a large extent.

On the other hand, if the position of CBM of the light absorbing layer is too low, there is a problem that the barrier of the n-type semiconductor layer is relatively elevated, the carriers generated at the p-type light absorbing layer cannot pass over the n-type semiconductor layer, and the current density cannot be made high. This causes a serious problem when the current density is increased.

As illustrated in FIG. 3, the CBM of the light absorbing layer material such as a Cu—In—Te system is higher than the CBM of ZnO and is lower than the CBM of ZnS. Therefore, when the substitution ratio of S, which is designated as x, is adjusted in a material having a composition represented by the formula ZnO₁₋ₓSₓ, the CBM of ZnO₁₋ₓSₓ can be continuously controlled to lie between the CBM of ZnO and the CBM of ZnS. Furthermore, similarly, since the CBM of the light absorbing layer material such as a Cu—In—Te system is higher than the CBM of ZnO and is lower than the CBM of MgO, when the substitution ratio of Mg, which is designated as a, is adjusted for a material having a composition represented by Zn_{1-z}Mg_{z}O, the CBM of Zn_{1-z}Mg_{z}O can be continuously controlled between the CBM of ZnO and the CBM of MgO. Also, when a portion of Zn is substituted with a carrier such as Al, and thereby the substitution ratios y and z are changed, the Fermi levels of Zn_{1-y}Al_{y}O₁₋ₓSₓ and Zn_{1-y-z}Mg_{z}Al_{y}O can be controlled without a large shift in the CBM. Even if the substituent element of Zn is not only Al but also at least any one of B, In and Ga, the Fermi level can be similarly controlled without a large shift in the CBM.

Furthermore, the composition of Ga_{α}Al_{1-α}P can be adjusted by adjusting the ratio of GaP and AlP so as to eliminate the band offset of the CBM of the light absorbing layer material such as a Cu—In—Te system and the CBM of the n-type semiconductor layer 4. The control of the Fermi level is made possible without a large shift in the CBM, by controlling the carrier concentration while the CBM offset is optimized. It is still acceptable for Ga_{α}Al_{1-α}P to contain In. Meanwhile, besides such intentional addition, there are occasions in which when, for example, CIGS such as Cu(In, Ga)Se₂ is used in the p-type light absorbing layer 3, the element In of CIGS may be incorporated into the n-type semiconductor layer 4 through diffusion. When the composition is represented by the formula Ga_{α}Al_{1-α-}βInβP, β is such that 0<β≦0.1, and desirably 0<β≦0.05.

As described above, when the loss of recombination at the p-n interface is suppressed and the Fermi level is controlled as a result of the optimization of the CBM offset, even in the case where the amount of light irradiation is small, a high open circuit voltage is easily obtained, and the conversion efficiency can be enhanced.

Meanwhile, in the case of using a material based mainly on GaP for the n-type semiconductor layer 4, if CuInS₂ or CuInTe₂ is selected as the p-type light absorbing layer 3, since the CBM of the n-type semiconductor layer 4 is lower than the CBM of the p-type light absorbing layer 3, and it is disadvantageous in the enhancement of the open circuit voltage, it is desirable to substitute a portion of S or Te with Se. Furthermore, in the case of compounds Se (CuInSe₂ and CuGaSe₂), or in the case where a portion has been substituted with S or Te, since the lattice constants of the p-type light absorbing layer 3 and the n-type semiconductor 4 are very close to each other, the epitaxial growth may also be easily achieved.

The method of determining the position of the Fermi level of an n-type semiconductor will be described. When the carrier concentration is designated as n, the carrier concentration is represented by the following equations (1) and (2). Therefore, the difference between the energy of the conduction band and the energy of the Fermi level is expressed by the following equation (3).

$$\begin{matrix}\begin{matrix}n = {2 [ \frac{2 π {m}_{n} kT}{{h}^{2}} ]}^{3 / 2} exp [ - \frac{{E}_{c} - {E}_{f}}{kT} ] \\ = {N}_{c} exp [ - \frac{{E}_{c} - {E}_{f}}{kT} ]\end{matrix} & Equation 1 \\ {N}_{c} ≡ {2 [ \frac{2 π {m}_{n} kT}{{h}^{2}} ]}^{3 / 2} & Equation 2 \\ {E}_{c} - {E}_{f} = kT ln [ \frac{{N}_{c}}{n} ] & Equation 3\end{matrix}$$

This implies that as the carrier concentration increases, the Fermi level approaches closer to the conduction band. In regard to the compound of ZnO₁₋ₓSₓ, electron doping can be carried out by substituting a portion of Zn having a formal valence of 2+ with an element having a formal valence of 3+ such as B, Al, Ga or In, and the Fermi level can be shifted to the vicinity of the conduction band. Furthermore, the difference between the CBM and the Fermi level, E_{c}-E_{f}, can be determined from the activation gap of the electrical resistivity by the following equation 4:

$$ρ = {ρ}_{n} exp [ - \frac{{E}_{c} - {E}_{f}}{kT} ] \qquad Equation 4$$

E_{C}, E_{f}, mₙ, k, T, h and ρₙ represent the energy of the conduction band, the energy of the Fermi level, the mass of an electron, the Boltzmann constant, the absolute temperature, the Planck constant, and a constant, respectively.

The difference between the CBM and the Fermi level of the p-type light absorbing layer 3 can be determined in the same manner as in the case of the n-type semiconductor layer 4 by the following equations:

$$\begin{matrix}\begin{matrix}n = {2 [ \frac{2 π {m}_{p} kT}{{h}^{2}} ]}^{3 / 2} exp [ - \frac{{E}_{f} - {E}_{v}}{kT} ] \\ = {N}_{v} exp [ - \frac{{E}_{f} - {E}_{v}}{kT} ]\end{matrix} & Equation 5 \\ {N}_{v} ≡ {2 [ \frac{2 π {m}_{n} kT}{{h}^{2}} ]}^{3 / 2} & Equation 6 \\ ρ = {ρ}_{n} exp [ - \frac{{E}_{c} - {E}_{f}}{kT} ] & Equation 7\end{matrix}$$

E_{f}, Eᵥ, mₚ, k, T, h and ρₚ represent the energy of the conduction band, the energy of the Fermi level, the mass of a hole (an electron hole), the Boltzmann constant, the absolute temperature, the Planck constant, and a constant, respectively.

A suitable p-type light absorbing layer 3 and a suitable n-type semiconductor layer 4 may be appropriately designed and selected from the CBM and the Fermi level as described above.

For example, in regard to the compound Zn_{1-y}Al_{y}O_{0.3}S_{0.7}, since the activation energy decreases from 150 meV at y=0.01 to 60 meV at y=0.02, it can be confirmed that the position of the Fermi level increases by 90 meV over the range of from y=0.01 to y=0.02 (the two values are values obtained in Example 1A and Example 1B). Accordingly, the open circuit voltage also increases. Also in regard to the p-type light absorbing layer 3, the Fermi level approaches closer to the valence band along with an increase in the carrier concentration, and this is led to an increase in the open circuit voltage.

Hereinafter, the photoelectric conversion element of the embodiment will be described with reference to the conceptual diagram of the photoelectric conversion element of the embodiment illustrated in FIG. 1. The photoelectric conversion element of FIG. 1 includes a substrate 1 formed from, for example, soda lime glass (blue plate glass); a lower electrode 2 formed on the soda lime glass plate 1; a p-type light absorbing layer 3 formed on the lower electrode 2; an n-type semiconductor layer 4 formed on the p-type light absorbing layer 3; a semi-insulating layer 5 formed on the n-type semiconductor layer 4; a transparent electrode 6 formed on the semi-insulating layer 5; and an upper electrode 7 and an antireflective film 8 formed on the transparent electrode 6.

(Method of Producing Photoelectric Conversion Element)

According to the embodiment, first, a lower electrode 2 is formed on a substrate 1. The lower electrode 2 is a metal layer composed of an electrically conductive material such as molybdenum (Mo). The method of forming the lower electrode 2 may be, for example, a thin film forming method, such as sputtering using a target formed of metal Mo.

After the lower electrode 2 is formed on the substrate 1, a p-type light absorbing layer 3 is formed on the lower electrode 2. Examples of the method of forming the p-type light absorbing layer 3 include thin film forming methods such as sputtering and vapor deposition.

In a method of using sputtering, it is preferable to bring the substrate temperature to 10° C. to 400° C. in an atmosphere containing Ar, and it is more preferable to performing sputtering at 250° C. to 350° C. If the temperature of the substrate 1 is too low, the p-type light absorbing layer 3 thus formed has poor crystallinity. On the other hand, if the temperature is too high, the crystal grains of the p-type light absorbing layer 3 become excessively large, and this may cause a decrease in the conversion efficiency of the photoelectric conversion element. After the p-type light absorbing layer 3 is formed, annealing may be carried out in order to control the crystal grain growth.

After the p-type light absorbing layer 3 is formed, an n-type semiconductor layer 4 is formed on the p-type light absorbing layer 3. Examples of the method of forming the n-type semiconductor layer 4 include sputtering, vapor deposition, chemical vapor deposition (CVD), and molecular beam epitaxy (MBE).

When the n-type semiconductor layer 4 is formed by sputtering, it is preferable to bring the substrate temperature to 10° C. to 300° C., and it is more preferable to perform sputtering at 200° C. to 250° C. If the temperature of the substrate is too low, the n-type semiconductor layer 4 thus formed has poor crystallinity. On the other hand, if the temperature is too high, a material having an intended crystal structure may not be obtained, and therefore, it is difficult to form an intended n-type semiconductor layer 4.

After the n-type semiconductor layer 4 is formed, a semi-insulating layer 5 suppressing any leak current is formed on the n-type semiconductor layer 4. A transparent electrode 6 is then formed on the semi-insulating layer 5, and an upper electrode 7 is formed on the transparent electrode 6. It is preferable to form an antireflective film 8 on the upper electrode 7. Meanwhile, the semi-insulating layer 5 may not be provided if the resistance value of the n-type semiconductor layer 4 is large.

In the descriptions given above, some examples of the p-type light absorbing layer are described, but other photoelectric conversion elements including other p-type light absorbing layer 3 can also give the same effects as the embodiment described above.

### Example 1A

On a substrate formed from soda lime glass and having a size of 25 mm in length×15 mm in width×1 mm in thickness, a lower electrode formed from Mo is formed by sputtering in an argon (Ar) gas stream using a target composed of elemental Mo. The thickness of the lower electrode is set to 600 nm. On the Mo lower electrode on the soda lime glass plate, a p-type light absorbing layer is formed by performing sputtering in an Ar gas stream using a target of Cu:In:Te=1:3:5. The thickness is set to 1.5 μm. Subsequently, an n-type semiconductor layer is formed by sputtering using a target of Zn:Al:O:S=99:1:30:70 by molar ratio. The thickness is set to 50 nm. For the semi-insulating layer, an n-type semiconductor layer is formed by performing sputtering using a target of i-ZnO or Zn:O:S=100:30:70 by molar ratio. The thickness is set to 200 nm. If the resistance of the n-type semiconductor layer is high, this semi-insulating layer may not be provided. Next, an upper electrode formed from Al and having a thickness of 1 μm, and an antireflective film layer formed from SiN and having a thickness of 100 nm are formed by a conventional film forming method. Thereby, a photoelectric conversion element of the embodiment can be obtained.

### Example 1B

A photoelectric conversion element of Example 1B is obtained by the same method as that used in Example 1A, except that a target of Zn:Al:O:S=98:2:30:70 by molar ratio is used in the sputtering of the n-type semiconductor layer.

### Example 1C

A photoelectric conversion element of Example 1C is obtained by the same method as that used in Example 1A, except that a target of Zn:Al:O:S=99:1:20:80 by molar ratio is used in the sputtering of the n-type semiconductor layer.

### Example 1D

A photoelectric conversion element of Example 1D is obtained by the same method as that used in Example 1A, except that a target of Zn:Al:O:S=98:2:20:80 by molar ratio is used in the sputtering of the n-type semiconductor layer.

### Example 1E

A photoelectric conversion element of Example 1E is obtained by the same method as that used in Example 1A, except that a target of Zn:Mg:Al:O=69:30:1:100 by molar ratio is used in the sputtering of the n-type semiconductor layer.

### Example 1F

A photoelectric conversion element of Example 1F is obtained by the same method as that used in Example 1A, except that a target of Zn:Mg:A:O=68:30:2:100 by molar ratio is used in the sputtering of the n-type semiconductor layer.

### Example 1G

A photoelectric conversion element of Example 1G is obtained by the same method as that used in Example 1A, except that a target of Zn:Mg:A:O=67:28:5:100 by molar ratio is used in the sputtering of the n-type semiconductor layer.

### Example 1H

A photoelectric conversion element of Example 1H is obtained by the same method as that used in Example 1A, except that a target of Zn:Al:O:S=95:5:20:80 by molar ratio is used in the sputtering of the n-type semiconductor layer.

### Comparative Example 1A

A photoelectric conversion element of Comparative Example 1A is obtained by the same method as that used in Example 1A, except that a target of Zn:Mg:O=70:30:100 by molar ratio is used in the sputtering of the n-type semiconductor layer.

### Comparative Example 1B

A photoelectric conversion element of Comparative Example 1B is obtained by the same method as that used in Example 1, except that a layer composed of CdS is formed as the n-type semiconductor layer. Meanwhile, the layer composed of CdS is formed by a chemical solution growth method. Also, the layer thickness is set to 100 nm.

### Comparative Example 1C

A photoelectric conversion element of Comparative Example 1C is obtained by the same method as that used in Example 1A, except that a target of Zn:O:S=100:30:70 by molar ratio is used in the sputtering of the n-type semiconductor layer.

For each of the photoelectric conversion elements of Examples 1A to 1H and Comparative Examples 1A to 1C, the composition of the n-type semiconductor layer and the open circuit voltage (V) were measured. The results are summarized in Table 1. Meanwhile, the composition of the n-type semiconductor layer is measured by energy dispersive X-ray spectroscopy (EDX), after a calibration by measuring a sample with a known composition. The EDX measurement is carried out by chipping the laminated films on top of the n-type semiconductor layer through ion milling of the central area of the photoelectric conversion element, and making a TEM observation of the cross-section at a magnification of 500,000 times, while at the same time, examining the composition from the average composition obtained at five points. The five-point determination method is performed such that a cross-sectional TEM image at a magnification of 500,000 times is equally divided into 5 sections in the thickness direction and the perpendicular direction, and the measurement is made at the centers of the divided areas. The open circuit voltage value was obtained by using a voltage source and a multimeter under the irradiation of pseudo-sunlight at AM 1.5 by means of a solar simulator, changing the voltage of the voltage source, and thereby measuring the voltage at which the current under the irradiation of pseudo-sunlight was 0 mA.

TABLE 1

| | n-type semiconductor | Open circuit |
|---|---|---|
| Example | layer | voltage (V) |
| Example 1A | Zn_{0.99}Al_{0.01}O_{0.3}S_{0.7} | 0.40 |
| Example 1B | Zn_{0.98}Al_{0.02}O_{0.3}S_{0.7} | 0.42 |
| Example 1C | Zn_{0.99}Al_{0.01}O_{0.2}S_{0.8} | 0.38 |
| Example 1D | Zn_{0.98}Al_{0.02}O_{0.2}S_{0.8} | 0.40 |
| Example 1E | Zn_{0.69}Mg_{0.3}Al_{0.01}O | 0.34 |
| Example 1F | Zn_{0.68}Mg_{0.3}Al_{0.02}O | 0.37 |
| Example 1G | Zn_{0.67}Mg_{0.28}Al_{0.05}O | 0.36 |
| Example 1H | Zn_{0.95}Al_{0.05}O_{0.3}S_{0.7} | 0.38 |
| Comparative | Zn_{0.7}Mg_{0.3}O | 0.30 |
| Example 1A | | |
| Comparative | CdS | 0.30 |
| Example 1B | | |
| Comparative | ZnO_{0.3}S_{0.7} | 0.32 |
| Example 1C | | |

From the above Table 1, Examples 1A to 1H exhibit high voltages as compared with Comparative Examples 1A to 1C, and thus, it can be seen that the present embodiment is effective.

### Example 2A

On a substrate formed from soda lime glass and having a size of 25 mm in length×15 mm in width×1 mm in thickness, a lower electrode formed from Mo is formed by sputtering in an Ar gas stream using a target composed of elemental Mo. The thickness of the lower electrode is set to from 500 nm to 1 μm. On the Mo lower electrode on the soda lime glass plate, a p-type light absorbing layer is formed by performing sputtering in an Ar gas stream using a target of Cu:In:Te=1:3:5. The thickness is set to 2 μm. Subsequently, an n-type semiconductor layer is formed by forming a film by MBE using an n-type GaP doped with sulfur (S) as a carrier at a concentration of 4.0×10¹⁵ cm⁻³. The thickness is set to 50 nm. For the semi-insulating layer, an n-type semiconductor layer is formed by performing sputtering using a target of i-ZnO or Zn:O:S=100:30:70. The thickness is set to 200 nm. If the resistance of the n-type semiconductor layer is high, this semi-insulating layer may not be provided. Next, an upper electrode formed from Al and having a thickness of 1 μm, and an antireflective film layer formed from SiN and having a thickness of 100 nm are formed by a conventional film forming method. Thereby, a photoelectric conversion element of the embodiment can be obtained.

### Example 2B

A photoelectric conversion element of Example 2B is obtained by the same method as that used in Example 2A, except that CuGaSe₂ is selected for the p-type light absorbing layer, and the concentration of S in the n-type semiconductor layer is set to 8.0×10⁻¹⁵ cm⁻³.

### Example 2C

A photoelectric conversion element of Example 2C is obtained by the same method as that used in Example 2A, except that CuGaSe₂ is selected for the p-type light absorbing layer, the carrier of the n-type semiconductor layer is changed to Se, and the concentration thereof is set to 5.0×10⁻¹⁵ cm⁻³.

### Comparative Example 2A

A photoelectric conversion element of Comparative Example 2A is obtained by the same method as that used in Example 2A, except that CuGaSe₂ is selected for the p-type light absorbing layer, and a GaP layer which is not doped with a carrier is used instead of the n-type semiconductor layer of Example 2A.

### Comparative Example 2B

A photoelectric conversion element of Comparative Example 2B is obtained by the same method as that used in Example 2A, except that a p-type GaP layer is used instead of the n-type semiconductor layer of Example 2A.

For each of the photoelectric conversion elements of Examples 2A to 2C and Comparative Examples 2A and 2B, the compositions of the p-type light absorbing layer and the n-type semiconductor layer and the open circuit voltage (V) were measured by the same method as that used in Examples 1A to 1H. The results are presented in Table 2.

TABLE 2

| | | n-type | Open |
|---|---|---|---|
| | p-type light | semiconductor | circuit |
| Example | absorbing layer | layer | voltage (V) |
| Example 2A | CuIn₃Te₅ | GaP (S: 4.0 × 10⁻¹⁵) | 0.20 |
| Example 2B | CuGaSe₂ | GaP (S: 8.0 × 10⁻¹⁵) | 0.42 |
| Example 2C | CuGaSe₂ | GaP (Se: 5.0 × 10⁻¹⁵) | 0.40 |
| Comparative | CuIn₃Te₅ | GaP (non-dope) | 0.18 |
| Example 2A | | | |
| Comparative | CuGaSe₂ | GaP (non-dope) | 0.22 |
| Example 2B | | | |

From the above Table 2, in Example 2A as compared with Comparative Example 2A, and in Examples 2B and 2C as compared with Comparative Example 2B, the open circuit voltages can be increased by controlling the carrier concentration of GaP, and thus, it can be seen that the present embodiment is effective.

### Example 3A

Photoelectric conversion elements of Example 3A are obtained by the same method as that used in Example 1A, except that the values of x and y in the composition of Zn_{1-y}Al_{y}O₁₋ₓSₓ of the n-type semiconductor layer are changed to the values indicated in Table 3. The n-type semiconductor layer was formed by appropriately varying the composition by performing sputtering using targets of Zn:Al:O:S with different compositions.

For the photoelectric conversion elements thus obtained having different amounts of x and different amounts of y, the open circuit voltages (V) were measured by the same method as that used in Examples 1A to 1H. The results are presented in Table 3.

TABLE 3

| | | Open circuit |
|---|---|---|
| x | y | voltage (V) |
| 0.2 | 0.00 | 0.36 |
| 0.2 | 0.01 | 0.38 |
| 0.2 | 0.02 | 0.40 |
| 0.2 | 0.05 | 0.36 |
| 0.2 | 0.10 | 0.20 |
| 0.3 | 0.00 | 0.32 |
| 0.3 | 0.01 | 0.40 |
| 0.3 | 0.02 | 0.42 |
| 0.3 | 0.05 | 0.38 |
| 0.3 | 0.10 | 0.30 |
| 0.4 | 0.00 | 0.10 |
| 0.4 | 0.01 | 0.12 |
| 0.4 | 0.02 | 0.13 |
| 0.4 | 0.05 | 0.00 |
| 0.4 | 0.10 | — |

From the above Table 3, the open circuit voltage increases as a result of changing the value of x and thereby adjusting the position of CBM. Furthermore, the open circuit voltage can be further increased by appropriately adjusting the Fermi level (approaching the conduction band) with y.

### Example 3B

Photoelectric conversion elements of Example 3B are obtained by the same method as that used in Example 1A, except that the values of x and y in the composition of Zn_{1-y}Al_{y}O₁₋ₓSₓ of the n-type semiconductor layer are changed to the values indicated in Table 4, and a target of cu:In:Te=0.8:1:2 by molar ratio is used for the p-type light absorbing layer. The n-type semiconductor layer was formed by appropriately varying the composition by performing sputtering using targets composed of Zn, Al, O and S at different compositions.

For the photoelectric conversion elements thus obtained having different amounts of y, the open circuit voltages (V) were measured by the same method as that used in Examples 1A to 1H. The results are presented in Table 4.

TABLE 4

| | | Open circuit |
|---|---|---|
| x | y | voltage (V) |
| 0.8 | 0.00 | 0.10 |
| 0.8 | 0.01 | 0.12 |

From the above Table 4, it can be seen that the open circuit voltage is enhanced by adjusting the Fermi level (approaching the conduction band) with y.

### Example 3C

Photoelectric conversion elements of Example 3C are obtained by the same method as that used in Example 1A, except that the values of x and y in the composition of Zn_{1-y}In_{y}O₁₋ₓSₓ of the n-type semiconductor layer are changed to the values indicated in Table 5. The n-type semiconductor layer was formed by appropriately varying the composition by performing sputtering using targets composed of Zn, In, O and S at different compositions.

For the photoelectric conversion elements thus obtained having different amounts of y, the open circuit voltages (V) were measured by the same method as that used in Examples 1A to 1H. The results are presented in Table 5.

TABLE 5

| | | Open circuit |
|---|---|---|
| x | y | voltage (V) |
| 0.7 | 0.00 | 0.32 |
| 0.7 | 0.01 | 0.36 |
| 0.7 | 0.02 | 0.40 |
| 0.7 | 0.05 | 0.35 |
| 0.7 | 0.10 | — |

From the above Table 5, it can be seen that there exists a region where the open circuit voltage exhibits the maximum value, as the Fermi level is appropriately adjusted (approaching the conduction band) with y. Meanwhile, in the case of y=0.05, there is a possibility that a trace amount of impurities have been incorporated.

### Example 3D

Photoelectric conversion elements of Example 3D are obtained by the same method as that used in Example 1A, except that the value of y in the composition of Zn_{0.7-y}Mg_{0.3}Al_{y}O (M=Al) of the n-type semiconductor layer is changed to the values indicated in Table 6. The n-type semiconductor layer was formed by appropriately varying the composition by performing sputtering using targets composed of Zn, Mg, Al and O at different compositions.

For the photoelectric conversion elements thus obtained having different amounts of y, the open circuit voltages (V) were measured by the same method as that used in Examples 1A to 1H. The results are presented in Table 6.

### Example 3E

Photoelectric conversion elements of Example 3E are obtained by the same method as that used in Example 1A, except that the value of y in the composition of Zn_{0.7-y}Mg_{0.3}In_{y}O (M=In) of the n-type semiconductor layer is changed to the values indicated in Table 6. The n-type semiconductor layer was formed by appropriately varying the composition by performing sputtering using targets composed of Zn, Mg, In and O at different compositions.

For the photoelectric conversion elements thus obtained having different amounts of y, the open circuit voltages (V) were measured by the same method as that used in Examples 1A to 1H. The results are presented in Table 6.

TABLE 6

| | | Open circuit |
|---|---|---|
| M | y | voltage (V) |
| Al | 0.00 | 0.30 |
| Al | 0.01 | 0.34 |
| Al | 0.02 | 0.36 |
| Al | 0.05 | 0.40 |
| Al | 0.10 | 0.34 |
| In | 0.00 | 0.30 |
| In | 0.01 | 0.34 |
| In | 0.02 | 0.37 |
| In | 0.05 | 0.36 |
| In | 0.10 | — |

From the above Table 6, it can be seen that the open circuit voltage is enhanced by adjusting the Fermi level (approaching the conduction band) with y, and thus, the present embodiment is effective.

### Examples 3F to 3H, Comparative Examples 3F to 3H

Photoelectric conversion elements of Examples 3F to 3H and Comparative Examples 3F to 3H are obtained by the same method as that used in Example 1A, except that the values indicated in Table 7 are set for the p-type light absorbing layer and the n-type semiconductor layer. The p-type light absorbing layer and the n-type semiconductor layer were formed by appropriately varying the compositions by performing sputtering using targets composed of the constituent elements indicated in Table 7 at different compositions.

For the photoelectric conversion elements thus obtained, the open circuit voltages (V) were measured by the same method as that used in Examples 1A to 1H. The results are presented in Table 7.

TABLE 7

| | | n-type | Open |
|---|---|---|---|
| | p-type light | semiconductor | circuit |
| Example | absorbing layer | layer | voltage (V) |
| Example 3F | CuIn_{0.7}Ga_{0.3}Se₂ | Zn_{0.99}Al_{0.01}O_{0.3}S_{0.7} | 0.35 |
| Comparative | CuIn_{0.7}Ga_{0.3}Se₂ | ZnO_{0.3}S_{0.7} | 0.31 |
| Example 3F | | | |
| Example 3G | CuIn_{0.3}Ga_{0.7}Se₂ | Zn_{0.99}Al_{0.01}O_{0.3}S_{0.7} | 0.42 |
| Comparative | CuIn_{0.3}Ga_{0.7}Se₂ | ZnO_{0.3}S_{0.7} | 0.35 |
| Example 3G | | | |
| Example 3H | CuGaSe₂ | Zn_{0.99}Al_{0.01}O_{0.3}S_{0.7} | 0.46 |
| Comparative | CuGaSe₂ | ZnO_{0.3}S_{0.7} | 0.41 |
| Example 3H | | | |

From the above Table 7, when Example 3F is compared with Comparative Example 3F, Example 3G with Comparative Example 3G, and Example 3H with Comparative Example 3H, it can be seen that the respective Examples resulted in higher open circuit voltages (V) as compared with the respective Comparative Examples.

In the embodiments and the Examples, the composition of the p-type light absorbing layer is described as CuIn₁₋ₓGaₓSe₂ or the like, but the element ratios may be slightly changed. Among them, for example, in the case of CuIn₁₋ₓGaₓSe₂, it is desirable that the ratio Cu/(In +Ga) be equal to or greater than 0.6 and equal to or less than 1.2, and that the ratio Se/(In +Ga) be equal to or greater than 1.95 and equal to or less than 2.2, because the substance forms a single phase with satisfactory crystallinity. In the case of CuIn₃Te₃, it is preferable that the ratio Cu/In be equal to or greater than 0.25 and equal to or less than 0.40, and that the ratio In/Te be equal to or greater than 0.50 and equal to or less than 0.70, because the substance forms a single phase with satisfactory crystallinity.

The slight changes in the element ratio are also applied to the ZnOS system of the n-type semiconductor layer. In the case of Zn_{1-y}M_{y}O₁₋ₓSₓ, the ratio (Zn+M)/(O+S) is preferably equal to or greater than 0.9 and equal to or less than 1.1, for the reason that a single phase is likely to be obtained.

When the photoelectric conversion element of the present invention is used in solar cells, a solar cell having a high open circuit voltage and high efficiency can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion element comprising:
a p-type light absorbing layer containing copper (Cu), at least one or more Group IIIb elements selected from the group including aluminum (Al), indium (In) and gallium (Ga), and at least one or more elements selected from the group including oxygen (O), sulfur (S), selenium (Se) and tellurium (Te); and
an n-type semiconductor layer formed on the p-type light absorbing layer and represented by any one of Zn_{1-y}M_{y}O₁₋ₓSₓ, Zn_{1-y-z}Mg_{z}M_{y}O (wherein M represents at least one element selected from the group including boron (B), Al, In and Ga), and gallium phosphide (GaP) with a controlled carrier concentration,
wherein x, y and z in the formulas Zn_{1-y}M_{y}O₁₋ₓSₓ and Zn_{1-y-z}Mg_{z}M_{y}O satisfy the following relations: 0.55≦x≦1.0, 0.001≦y≦0.05, and 0.002≦y+z≦1.0.

2. The element according to claim 1, wherein the GaP is doped with one or more carrier elements selected from the group including S, Se and Te.

3. The element according to claim 1, wherein the carrier concentration of the GaP is equal to or greater than 10¹⁴ cm⁻³ and equal to or less than 10²¹ cm⁻³.

4. The element according to claim 1, wherein z in the formula Zn_{1-y-z}Mg_{z}M_{y}O satisfies the relation: 0<z≦0.5.

5. The element according to claim 1, wherein the p-type light absorbing layer is a compound semiconductor having a chalcopyrite structure.

6. The element according to claim 1, wherein
the p-type light absorbing layer is CuIn₁₋ₓGaₓSe₂,
the ratio Cu/(In+Ga) of the p-type light absorbing layer is equal to or greater than 0.6 and equal to or less than 1.2 by element ratio, and
the ratio Se/(In+Ga) of the p-type light absorbing layer is equal to or greater than 1.95 and equal to or less than 2.2 by element ratio.

7. The element according to claim 1, wherein
the p-type light absorbing layer is CuIn₃Te₅,
the ratio Cu/In of the p-type light absorbing layer is equal to or greater than 0.25 and equal to or less than 0.40 by element ratio, and
the ratio In/Te of the p-type light absorbing layer is equal to or greater than 0.50 and equal to or less than 0.70 by element ratio.

8. The element according to claim 1, wherein
the n-type semiconductor layer is Zn_{1-y}M_{y}O₁₋ₓSₓ, and
the ratio (Zn+M)/(O+S) of the n-type semiconductor layer is equal to or greater than 0.9 and equal to or less than 1.1 by element ratio.

9. The element according to claim 1, wherein
the conduction band minimum of the p-type light absorbing layer is equal to or greater than 4.3 eV and equal to or less than 4.6 eV, and
z in the formula Zn_{1-y-z}Mg_{z}M_{y}O satisfies the relation: 0.15≦z≦0.3.

10. The element according to claim 1, wherein
the conduction band minimum of the p-type light absorbing layer is equal to or greater than 3.8 eV and equal to or less than 4.3 eV, and
z in the formula Zn_{1-y-z}Mg_{z}M_{y}O satisfies the relation: 0.15≦z≦0.5.

11. The element according to claim 1, wherein
the conduction band minimum of the p-type light absorbing layer is equal to or greater than 3.5 eV and equal to or less than 4.0 eV, and
z in the formula Zn_{1-y-z}Mg_{z}M_{y}O satisfies the relation: 0.2≦z≦0.5.

12. The element according to claim 1, wherein
the conduction band minimum of the p-type light absorbing layer is equal to or greater than 4.3 eV and equal to or less than 4.6 eV, and
x in the formula Zn_{1-y}M_{y}O₁₋ₓSₓ satisfies the relation: 0.55≦x≦0.7.

13. The element according to claim 1, wherein
the conduction band minimum of the p-type light absorbing layer is equal to or greater than 3.8 eV and equal to or less than 4.3 eV, and
x in the formula Zn_{1-y}M_{y}O₁₋ₓSₓ satisfies the relation: 0.6≦x≦0.8.

14. The element according to claim 1, wherein
the conduction band minimum of the p-type light absorbing layer is equal to or greater than 3.5 eV and equal to or less than 4.0 eV, and
x in the formula Zn_{1-y}M_{y}O₁₋ₓSₓ satisfies the relation: 0.65≦x≦1.0.

15. The element according to claim 1, wherein
z in the formula Zn_{1-y-z}Mg_{y}O satisfies the relation: 0<z≦0.5.

16. A solar cell using a photoelectric conversion element that comprises a p-type light absorbing layer containing copper (Cu), at least one or more Group IIIb elements selected from the group including aluminum (Al), indium (In) and gallium (Ga), and at least one or more elements selected from the group including oxygen (O), sulfur (S), selenium (Se) and tellurium (Te); and an n-type semiconductor layer formed on the p-type light absorbing layer and represented by any one of Zn_{1-y}M_{y}O₁₋ₓSₓ, Zn_{1-y-z}Mg_{z}M_{y}O (wherein M represents at least one element selected from the group including boron (B), Al, In and Ga), and gallium phosphide (GaP) with a controlled carrier concentration,
wherein x, y and z in the formulas Zn_{1-y}M_{y}O₁₋ₓSₓ and Zn_{1-y-z}Mg_{z}M_{y}O satisfy the following relations: 0.55≦x≦1.0, 0.001≦y≦0.05, and 0.002≦y+z≦1.0.

17. The solar cell according to claim 16, wherein the GaP is doped with one or more carrier elements selected from the group including S, Se and Te.

18. The solar cell according to claim 16, wherein the carrier concentration of the GaP is equal to or greater than 10¹⁴ cm⁻³ and equal to or less than 10²¹ cm⁻³.
